(19) United States
(12) Patent Application Publication
(10) Pub. No.: US 2018/0141306 A1
(43) Pub. Date: May 24, 2018

(54) DISPLAY PANEL AND DEVICE USING THE SAME

(71) Applicant: Wuhan China Star Optoelectronics Technology Co., Ltd., Wuhan (CN)

(72) Inventors: Hongqing CUI, Wuhan (CN); Guowei ZHA, Wuhan (CN)

(21) Appl. No.: 15/325,717

(22) PCT Filed: Dec. 23, 2016
(86) PCT No.: PCT/CN2016/111642

§ 371 Date: Jan. 12, 2017

(30) Foreign Application Priority Data
Nov. 24, 2016 (CN) 201611058634.8

(51) Int. Cl. B32B 7/02; G02B 1/11

(52) U.S. Cl. CPC B32B 7/02; G02B 1/11; B81B 2207/99; G02F 2203/03; G02F 2201/12; G02F 2201/38; G02F 2201/50

(57) ABSTRACT

A display panel and device are provided. The display panel comprises a cover glass, a first light modulating layer is disposed on the cover glass, the first light modulating layer includes at least two first microstructures, the first microstructures are configured for increasing a scattering rate of a ambient light, and a second light modulating layer is disposed on the first light modulating layer, the second light modulating layer includes at least two first microstructures spaced from each other, the second microstructures are configured for increasing a transmittance of the ambient light.

### FIELD OF THE INVENTION

The disclosure relates to display technology, and more particularly to a display panel and a device using the same.

### BACKGROUND OF THE INVENTION

The conventional display panel mainly achieves light emission by the active light emission principle of the display device. When the panel is irradiated by sunlight, the sunlight will reflect on a surface of a panel, thereby affecting a contrast of a display screen. It is particularly evident for an outdoor display device and indoor displays with strong lighting environments.

In a conventional display panel, the solution is to perform an anti-reflection treatment on a surface of the display device. As shown in FIG. 1, a conventional display panel is provided with a multilayer film 102 on a surface of the cover glass 101. This method mainly adopts the optical interference principle between layers to reduce the reflection of ambient light. The effect of the anti-reflection method depends on the optimal wavelength, and the optimal wavelength depends on the refractive index of the material and the material thickness. Thus, it is usually necessary to provide a multilayer film structure in order to enhance the antireflection effect. In addition, since the interference of light is more sensitive to the optical path, the anti-reflection effect is not ideal under high-angle reflection, thereby resulting in poor contrast.

Thus, it is necessary to provide a display panel and a display device to solve the problems of the prior art.

### SUMMARY OF THE INVENTION

The object of the disclosure is to provide a display panel and a display device for solving the technical problem of poor contrast in a conventional display panel.

In order to solve the aforementioned problem, the disclosure provides a display panel, which comprises:

a cover glass;

a first light modulating layer disposed on the cover glass, the first light modulating layer including at least two first microstructures, the first microstructures configured for increasing a scattering rate of an ambient light, a cross-sectional shape of the first microstructures being semicircular;

a second light modulating layer disposed on the first light modulating layer, the second light modulating layer including at least two second microstructures spaced mutually, the second microstructures configured for increasing a transmittance of the ambient light, the second microstructures including a top portion and a bottom portion, a first pitch being greater than a second pitch, wherein the first pitch is a pitch between the two top portions of the adjacent two second microstructures, and the second pitch is a pitch between the two bottom portions of the adjacent two second microstructures.

In the display panel of the disclosure, a radius of the first microstructures is 3-10 microns.

In the display panel of the disclosure, a length or a width of a bottom surface of the second microstructures is in the range of 100 to 900 nanometers.

In the display panel of the disclosure, a cross-sectional shape of the second microstructures is triangular or trapezoidal.

In the display panel of the disclosure, a thickness of the second microstructures is in the range of 100 to 1000 nanometers.

In the display panel of the disclosure, a projected area of the second microstructures on the cover glass is less than a projected area of the first microstructures on the cover glass.

In the display panel of the disclosure, two adjacent first microstructures are arranged at intervals, the second microstructures is disposed on an upper surface of the first microstructures and on the cover glass which is not covered by the first microstructures.

The disclosure further provides a display device, which includes a display panel, the display panel comprises:

a cover glass;

a first light modulating layer disposed on the cover glass, the first light modulating layer including at least two first microstructures, the first microstructures configured for increasing a scattering rate of an ambient light;

a second light modulating layer disposed on the first light modulating layer, the second light modulating layer including at least two second microstructures spaced mutually, the second microstructures configured for increasing a transmittance of the ambient light.

In the display device of the disclosure, a cross-sectional shape of the first microstructures is semicircular.

In the display device of the disclosure, a radius of the first microstructures is 3-10 microns.

In the display device of the disclosure, the second microstructures comprises a top portion and a bottom portion, a first pitch is greater than a second pitch, the first pitch is a pitch between the two top portions of the adjacent two second microstructures, and the second pitch is a pitch between the two bottom portions of the adjacent two second microstructures.

In the display device of the disclosure, a length or a width of a bottom surface of the second microstructures is in the range of 100 to 900 nanometers.

In the display device of the disclosure, a cross-sectional shape of the second microstructures is triangular or trapezoidal.

In the display device of the disclosure, a thickness of the second microstructures is in the range of 100 to 1000 nanometers.

In the display device of the disclosure, a projected area of the second microstructures on the cover glass is less than a projected area of the first microstructures on the cover glass.

In the display device of the disclosure, two adjacent first microstructures are arranged at intervals, the second microstructures is disposed on an upper surface of the first microstructures and the cover glass which is not covered by the first microstructures.

The display panel and display device of the disclosure reduce the reflection of ambient light through disposing two light modulating layers. One of the light modulating layers comprises a plurality of first microstructures for improving the scattering rate of ambient light and the other light modulating layer comprises a plurality of second microstructures for increasing the transmittance of ambient light. Since the transmittance of the ambient light is increased by the second microstructures, and the transmitted ambient light is scattered by the first microstructures, the reflection of the environmental light is reduced. Additionally, the anti-reflection effects are not limited by the optical path, thereby increasing the contrast of the display panel.

### DESCRIPTION OF THE DRAWINGS

FIG. 1 is a cross-sectional view of the conventional display panel.

FIG. 2 is a cross-sectional view of a display panel according to an embodiment of the disclosure.

FIG. 3 is an enlarged schematic view of a second microstructure in FIG. 2.

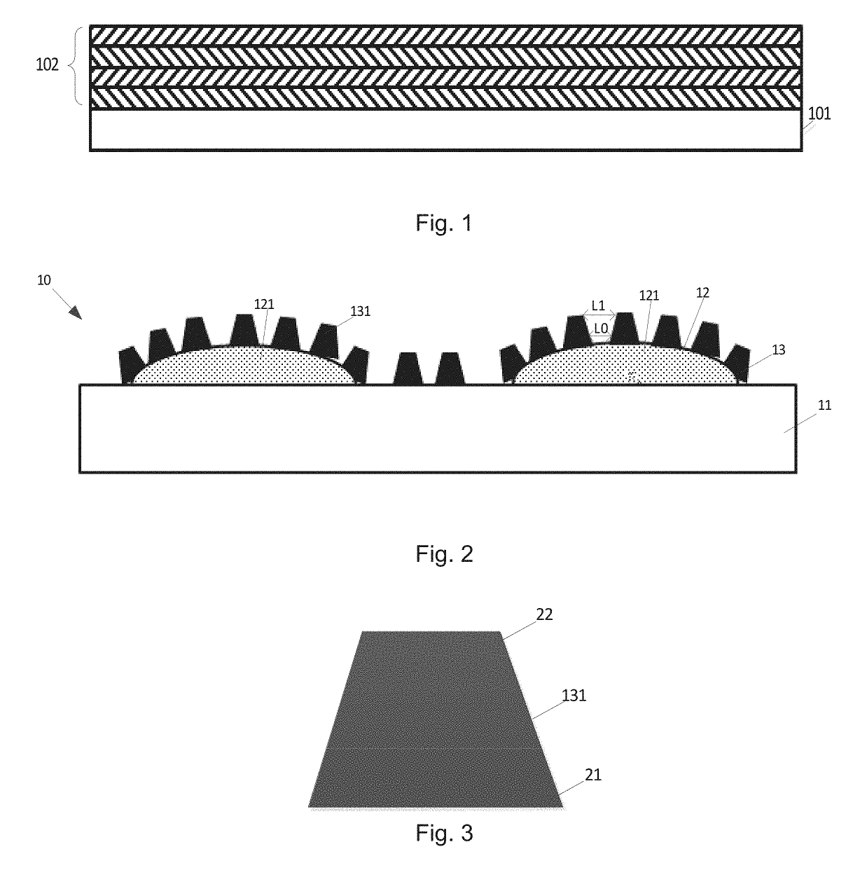

### DETAILED DESCRIPTION OF THE PREFERRED EMBODIMENTS

This description of the exemplary embodiments is intended to be read in connection with the accompanying drawings, which are to be considered part of the entire written description. In the description, terms such as “lower”, “upper”, “horizontal”, “vertical”, “above”, “below”, “up”, “down”, “top”, and “bottom”, as well as derivatives thereof, should be construed to refer to the orientation as then described or as shown in the drawing under discussion. These terms are for convenience of description and do not require that the apparatus be constructed or operated in a particular orientation, and do not limit the scope of the invention. Referring to the drawings of the disclosure, similar components are labeled with the same number.

Refer to FIG. 2, which is a cross-sectional view of a display panel according to an embodiment of the disclosure.

As shown in FIG. 2, a display panel 10 of the disclosure comprises a cover glass 11, a first light modulating layer 12, and a second light modulating layer 13. The first light modulating layer 12 is disposed on the cover glass 11. The first light modulating layer 12 includes two first microstructures 121. The first microstructures 121 are configured for increasing a scattering rate of an ambient light.

A cross-sectional shape of the first microstructures 121 is an arc, and is preferably semicircular. Since the arc-shaped structure is more conducive to the scattering of ambient light, it is possible to better reduce the reflection of ambient light.

When the cross-sectional shape of the first microstructures 121 is semicircular, a radius of the first microstructures 121 is 3-10 microns. A material of the first microstructures 121 is glass. When the radius of the first microstructures 121 is within this range, scattering of the ambient light is more facilitated, and the display panel can be prevented from being blurred. The manufacturing method of the first microstructures 121 can be prepared by a conventional microelectronic etching process, and is not limited to the method.

The second light modulating layer 13 is disposed on the first light modulating layer 12. The second light modulating layer 13 includes at least two second microstructures 131, two adjacent second microstructures 131 are arranged at intervals. The second microstructures 131 are configured for increasing a transmittance of the ambient light. When two adjacent first microstructures 121 are arranged at intervals, the second microstructures 131 are disposed on an upper surface of the first microstructures 121 and on the cover glass 11 which is not covered by the first microstructures 121.

Refer to FIGS. 2-3, the second microstructures 131 each include a top portion 22 and a bottom portion 21. A pitch L1 between the top portions 22 of the two adjacent second microstructures 131 is referred to as a first pitch. A pitch L2 between the bottom portions 21 of the two adjacent second microstructures 131 is referred to as a second pitch. Preferably, the first pitch L1 is greater than the second pitch LO. Namely, a cross section of the second microstructures 131 is a narrow top shape and a wide bottom shape, thereby enabling the ambient light to better enter into the cover glass without reflection. The cross-sectional shape of the second microstructures 131 is triangular or trapezoidal, and so on.

It can be understood that the second microstructures 131 comprise a bottom surface and a top surface. The bottom surface is adjacent to the first microstructures 121 (such as a surface adjacent to the first microstructures). The top surface is remote from the first microstructures 121. A length or a width of the bottom surface of the second microstructures 131 is in the range of 100 to 900 nanometers. If the length or width is too small, it is not conducive for the ambient light to pass through. If the length or width is too large, the transmittance of the ambient light becomes weaker, and the anti-reflection effect is poor.

A thickness of the second microstructures 131 is in the range of 100 to 1000 nanometers. If the thickness is too large, a size of the display panel might be increased. If the thickness is too small, it is not conducive to improve the transmittance of the ambient light.

A projected area of the second microstructures 131 on the cover glass 11 is less than a projected area of the first microstructures 121 on the cover glass 11. Namely, a size of the first microstructures 121 is greater than a size of the second microstructures 131, thereby better reducing the reflection of the ambient light. The second microstructures 131 can be manufactured by an anodizing porous aluminum template through a roll-to-roll nano imprinting process.

The manufacturing method of the display panel mentioned above comprises the following steps.

In a step S101, a first light modulating layer 12 is formed on a surface of an outer surface of a cover glass 11.

In a step S102, the first light modulating layer 12 is etched for forming a plurality of first microstructures 121.

In a step S103, a certain thickness of a second light modulating layer 13 is deposited on the surface of the first microstructures 121.

In a step S104, a photoresist is coated on a surface of the second light modulating layer 13.

In a step S105, a photoresist mask is prepared on a surface of the photoresist through using a porous aluminum imprint template.

For example, the porous aluminum imprint template is manufactured through an anodizing electrolytic aluminum manner. The method of manufacturing the porous aluminum imprint template through the anodizing electrolytic aluminum manner comprises: forming a electrochemical reaction platform and using oxalic acid or sulfuric acid as a electrolyte, an aluminum electrode and a carbon electrode being used as a anode and a cathode, respectively, and forming a porous structure on a surface of the aluminum electrode through applying a DC voltage; the aluminum electrode is then placed in a phosphoric acid solution, a diameter of the porous structure being made larger and a depth of the porous structure being made deeper by an oxidation of phosphoric acid due to a specific surface area of the porous structure being larger. Repeating the above electrochemical and phosphoric acid oxidation processes allows the diameter and depth of the porous aluminum to reach the desired requirements of the nano-imprint template.

In a step S106, the second light modulating layer 13 is etched by using a photoresist mask to form a second microstructure.

Since the second light modulating layer includes the second microstructures and a gap structure (i.e., an air gap), an effective refractive index of the ambient light is equivalent to a difference value between a refractive index of the second microstructures and a refractive index of air after the light enters into the second light modulating layer.

Since the second microstructures is a conical shape, i.e. as the ambient light is delivered from the outer surface to an interior portion of the second microstructures, an effective volume ratio of both of the air gap and the second microstructures changes. An effective volume of the second microstructures is increased, an effective volume of the air gap is decreased, and the effective refractive index of the second microstructures is also gradually increased, i.e. the second microstructures can be described as a structure with an equivalent refractive index gradually increased from outside to inside. With the increasing of the refractive index, a reflected light effect of the ambient light reflected on the surface of the cover glass is effectively reduced, thereby achieving the anti-reflection effect.

It can be understood that the display panel can comprise two or more first microstructures and second microstructures.

The display panel of the disclosure reduces the reflection of ambient light through disposing two of the light modulating layers. Besides, one of the light modulating layer comprises a plurality of first microstructures for improving the scattering rate of ambient light and the other light modulating layer comprises a plurality of second microstructures for increasing the transmittance of ambient light, since the transmittance of the ambient light is increased by the second microstructures, and the transmitted ambient light is scattered by the first microstructures. Additionally, the anti-reflection effects are not limited by the optical path, thereby increasing the contrast of the display panel. In addition, since only two light modulating layers are provided, the size of the display panel can be reduced, and the production cost can be reduced.

The disclosure further provides a display device, which includes a display panel as shown in FIG. 2. The display panel 10 comprises a cover glass 11, a first light modulating layer 12, and a second light modulating layer 13. The first light modulating layer 12 is disposed on the cover glass 11. The first light modulating layer 12 includes two first microstructures 121. The first microstructures 121 are configured for increasing a scattering rate of an ambient light.

A cross-sectional shape of the first microstructures 121 is an arc, and is preferably semicircular. Since the arc-shaped structure is more conducive to the scattering of ambient light, it is possible to better reduce the reflection of ambient light.

When the cross-sectional shape of the first microstructures 121 is semicircular, a radius of the first microstructures 121 is 3-10 microns. A material of the first microstructures 121 is glass. When the radius of the first microstructures 121 is within this range, scattering of the ambient light is more facilitated, and the display panel can be prevented from being blurred. The manufacturing method of the first microstructures 121 can be prepared by a conventional microelectronic etching process, and is not limited to the method.

The second light modulating layer 13 is disposed on the first light modulating layer 12. The second light modulating layer 13 includes at least two second microstructures 131 two adjacent second microstructures 131 are arranged at intervals. The second microstructures 131 are configured for increasing a transmittance of the ambient light. When two adjacent first microstructures 121 are arranged at intervals, the second microstructures 131 are disposed on an upper surface of the first microstructures 121 and on the cover glass 11 which is not covered by the first microstructures 121.

Refer to FIGS. 2-3, the second microstructures 131 include a top portion 22 and a bottom portion 21. A pitch L1 between the top portions 22 of the two adjacent second microstructures 131 is referred to as a first pitch. A pitch L2 between the bottom portions 21 of the two adjacent second microstructures 131 is referred to as a second pitch. Preferably, the first pitch L1 is greater than the second pitch L0. Namely, a cross section of the second microstructures 131 is a narrow top shape and a wide bottom shape, thereby enabling the ambient light to better enter into the cover glass without reflection. The cross-sectional shape of the second microstructures is triangular or trapezoidal, and so on.

A length or a width of the bottom surface of the second microstructures 131 is in the range of 100 to 900 nanometers. If the length or width is too small, it is not conducive for the ambient light to pass through. If the length or width is too large, the transmittance of the ambient light becomes weaker, and the anti-reflection effect is poor.

A thickness of the second microstructures 131 is in the range of 100 to 1000 nanometers. If the thickness is too large, a size of the display panel might be increased. If the thickness is too small, it is not conducive to improve the transmittance of the ambient light.

A projected area of the second microstructures 131 on the cover glass 11 is less than a projected area of the first microstructures 121 on the cover glass 11. Namely, a size of the first microstructures 121 is greater than a size of the second microstructures 131, thereby better reducing the reflection of the ambient light. The second microstructures 131 can be manufactured by an anodizing porous aluminum template through a roll-to-roll nano imprinting process.

The manufacturing method of the display panel mentioned above comprises the following steps.

In a step S101, a first light modulating layer 12 is formed on a surface of an outer surface of a cover glass 11.

In a step S102, the first light modulating layer 12 is etched for forming a plurality of first microstructures 121.

In a step S103, a certain thickness of a second light modulating layer 13 is deposited on the surface of the first microstructures 121.

In a step S104, a photoresist is coated on a surface of the second light modulating layer 13.

In a step S105, a photoresist mask is prepared on a surface of the photoresist through using a porous aluminum imprint template.

For example, the porous aluminum imprint template is manufactured through an anodizing electrolytic aluminum manner. The method of manufacturing the porous aluminum imprint template through the anodizing electrolytic aluminum manner comprises: forming an electrochemical reaction platform and using oxalic acid or sulfuric acid as an electrolyte, an aluminum electrode, and a carbon electrode being used as an anode and a cathode, respectively, and forming a porous structure on a surface of the aluminum electrode through applying a DC voltage; the aluminum electrode is then placed in a phosphoric acid solution, a diameter of the porous structure being made larger and a depth of the porous structure being made deeper by an oxidation of phosphoric acid due to a specific surface area of the porous structure being larger. Repeating the above electrochemical and phosphoric acid oxidation processes allows the diameter and depth of the porous aluminum to reach the desired requirements of the nano-imprint template.

In a step S106, the second light modulating layer 13 is etched by using a photoresist mask to form a second microstructure.

Since the second light modulating layer includes the second microstructures and a gap structure (i.e., an air gap), an effective refractive index of the ambient light is equivalent to a difference value between a refractive index of the second microstructures and a refractive index of air after the light enters into the second light modulating layer.

Since the second microstructures are a conical shape, i.e., as the ambient light is delivered from the outer surface to an interior portion of the second microstructures, an effective volume ratio of both of the air gap and the second microstructures changes. An effective volume of the second microstructures is increased, an effective volume of the air gap is decreased, and the effective refractive index of the second microstructures is also gradually increased, i.e., the second microstructures can be described as a structure with an equivalent refractive index gradually increased from outside to inside. With the increasing of the refractive index, a reflected light effect of the ambient light reflected on the surface of the cover glass is effectively reduced, thereby achieving the anti-reflection effect.

It can be understood that the display panel can comprise two or more first microstructures and second microstructures.

The display device of the disclosure reduces the reflection of ambient light through disposing two of the light modulating layers. Besides, one of the light modulating layer comprises a plurality of first microstructures for improving the scattering rate of ambient light and the other light modulating layer comprises a plurality of second microstructures for increasing the transmittance of ambient light, since the transmittance of the ambient light is increased by the second microstructures, and the transmitted ambient light is scattered by the first microstructures. Additionally, the anti-reflection effects are not limited by the optical path, thereby increasing the contrast of the display panel. In addition, since only two light modulating layers are provided, the size of the display panel can be reduced, and the production cost can be reduced.

The disclosure has been described with preferred embodiments thereof, and it is understood that many changes and modifications to the described embodiment can be carried out without departing from the scope and the spirit of the invention that is intended to be limited only by the appended claims.

What is claimed is:

1. A display panel, comprising:
a cover glass;
a first light modulating layer disposed on the cover glass, including at least two first microstructures configured for increasing a scattering rate of a ambient light, a cross-sectional shape of the first microstructures being semicircular;
a second light modulating layer disposed on the first light modulating layer, including at least two second microstructures spaced mutually and configured for increasing a transmittance of the ambient light, the second microstructures including a top portion and a bottom portion, a first pitch being greater than a second pitch, wherein the first pitch is a pitch between the two top portions of the adjacent two second microstructures, and the second pitch is a pitch between the two bottom portions of the adjacent two second microstructures.

2. The display panel according to claim 1, wherein a radius of the first microstructures is 3-10 microns.

3. The display panel according to claim 1, wherein a length or a width of a bottom surface of the second microstructures is in the range of 100 to 900 nanometers.

4. The display panel according to claim 1, wherein a cross-sectional shape of the second microstructures is triangular or trapezoidal.

5. The display panel according to claim 1, wherein a thickness of the second microstructures is in the range of 100 to 1000 nanometers.

6. The display panel according to claim 1, wherein a projected area of the second microstructures on the cover glass is less than a projected area of the first microstructures on the cover glass.

7. The display panel according to claim 1, wherein two adjacent first microstructures are arranged at intervals, the second microstructures are disposed on an upper surface of the first microstructures and on the cover glass which is not covered by the first microstructures.

8. A display device including a display panel, the display panel comprising:
a cover glass;
a first light modulating layer disposed on the cover glass, including at least two first microstructures configured for increasing a scattering rate of a ambient light;
a second light modulating layer disposed on the first light modulating layer, including at least two second microstructures spaced mutually and configured for increasing a transmittance of the ambient light.

9. The display device according to claim 8, wherein a cross-sectional shape of the first microstructures is semicircular.

10. The display device according to claim 9, wherein a radius of the first microstructures is 3-10 microns.

11. The display device according to claim 8, wherein the second microstructures comprise a top portion and a bottom portion, a first pitch is greater than a second pitch, the first pitch is a pitch between the two top portions of the adjacent two second microstructures, and the second pitch is a pitch between the two bottom portions of the adjacent two second microstructures.

12. The display device according to claim 11, wherein a length or a width of a bottom surface of the second microstructures is in the range of 100 to 900 nanometers.

13. The display device according to claim 8, wherein a cross-sectional shape of the second microstructures is triangular or trapezoidal.

14. The display device according to claim 8, wherein a thickness of the second microstructures is in the range of 100 to 1000 nanometers.

15. The display device according to claim 8, wherein a projected area of the second microstructures on the cover glass is less than a projected area of the first microstructures on the cover glass.

16. The display device according to claim 8, wherein two adjacent first microstructures are arranged at intervals, the second microstructures are disposed on an upper surface of the first microstructures and the cover glass which is not covered by the first microstructures.
